(19) United States
(12) Patent Application Publication
(10) Pub. No.: US 2026/0114171 A1
(43) Pub. Date: Apr. 23, 2026

(54) DISPLAY DEVICE AND ELECTRONIC APPARATUS INCLUDING THE SAME

(71) Applicant: Samsung Display Co., Ltd., Yongin-si, (KR)

(72) Inventors: EUNBYUL KIM, Yongin-si, (KR); HANBUM KWON, Yongin-si, (KR); YOUNGMIN AHN, Yongin-si, (KR)

(21) Appl. No.: 19/333,641

(22) Filed: Sep. 19, 2025

(30) Foreign Application Priority Data
Oct. 21, 2024 (KR) 10-2024-0143694

(51) Int. Cl. H10K 59/88; H10K 59/131; H10K 102/00

(52) U.S. Cl. CPC H10K 59/88; H10K 59/131; H10K 2102/351

(57) ABSTRACT

Provided is a display device including a display panel including a display region and a non-display region adjacent to the display region, a pixel disposed in the display region, a signal line disposed in the display region and the non-display region and electrically connected to the pixel, a signal pad disposed in the non-display region and electrically connected to the signal line, and a first dummy pad disposed in the non-display region and spaced apart from the signal pad. The signal pad includes a first conductive pattern electrically connected to an end of the signal line, an insulating pattern disposed on the first conductive pattern, and a second conductive pattern disposed on the insulating pattern. The first dummy pad includes the first conductive pattern and a dummy pattern disposed on the first conductive pattern. A hardness of the dummy pattern is higher than a hardness of the insulating pattern.

### CROSS-REFERENCE TO RELATED APPLICATIONS

This U.S. non-provisional patent application claims priority under 35 U.S.C. §119 of Korean Patent Application No. 10-2024-0143694, filed on Oct. 21, 2024, the entire contents of which are hereby incorporated by reference.

### BACKGROUND

The present disclosure herein relates to a display device and an electronic apparatus including the same, and more particularly, to a display device including a pad region and an electronic apparatus including the same.

Various display devices used for multimedia devices such as a television, a mobile phone, a tablet computer, a navigation system, and a game console are being developed. Electronic devices which include the display devices may include a keyboard and a mouse as an input device. The display devices itself may include an input sensor such as a touch panel as an input device.

A display device includes a display region which is activated in response to electrical signals. The display device may not only detect an input applied from the outside through the display region, but also display various images to provide information to a user.

A display device includes a display panel and a circuit board. The display panel may be connected to a main board via the circuit board. A driver chip may be mounted on the display panel. The driver chip may be electrically connected to the display panel via pads disposed in a non-display region of the display panel.

### SUMMARY

The present disclosure provides a display device and an electronic apparatus in which an indentation capable of detecting an initial process failure is formed on a rear surface of a display panel.

The present disclosure also provides a display device and an electronic apparatus with improved bonding reliability.

An embodiment of the inventive concept provides a display device including: a display panel including a display region and a non-display region adjacent to the display region; a pixel disposed in the display region; a signal line disposed in the display region and the non-display region and electrically connected to the pixel; a signal pad disposed in the non-display region and electrically connected to the signal line; and a first dummy pad disposed in the non-display region and located to be spaced apart from the signal pad, wherein the signal pad includes a first conductive pattern electrically connected to an end of the signal line, an insulating pattern disposed on the first conductive pattern, and a second conductive pattern disposed on the insulating pattern, the first dummy pad includes the first conductive pattern, and a dummy pattern disposed on the first conductive pattern, and a hardness of the dummy pattern is higher than a hardness of the insulating pattern.

In an embodiment, the dummy pattern and the second conductive pattern may include a same material.

In an embodiment, the dummy pattern may include metal.

In an embodiment, the hardness of the dummy pattern may be higher than a hardness of the first conductive pattern.

In an embodiment, the dummy pattern may have a thickness of about 1 μm to about 5 μm

In an embodiment, the dummy pattern may be disposed inside the first conductive pattern in a plan view.

In an embodiment, the first dummy pad may extend in one direction in a plan view, the dummy pattern may be provided in plurality, and the plurality of dummy patterns may be located to be spaced apart from each other in the one direction in a plan view.

In an embodiment, the first dummy pad may be electrically isolated.

In an embodiment, the signal pad and the first dummy pad may each be provided in plurality, the plurality of signal pads may include first signal pads extending in a first direction in a plan view, and the plurality of first dummy pads may include (1-1)-th dummy pads extending in the first direction in a plan view.

In an embodiment, the plurality of signal pads may further include second signal pads spaced apart from the first signal pads in a second direction crossing the first direction in a plan view, the second signal pads may extend in an oblique direction crossing the first direction and the second direction, the plurality of first dummy pads may further include (1-2)-th dummy pads spaced apart from the second signal pads in the second direction, and the (1-2)-th dummy pads may extend in an oblique direction crossing the first direction and the second direction.

In an embodiment, the first signal pads may be disposed in a central region of the plurality of signal pads in the second direction in a plan view, and the (1-1)-th dummy pads may be disposed in the central region in a plan view.

In an embodiment, the (1-2)-th dummy pads may be disposed in an outermost region of the plurality of signal pads within the second direction.

In an embodiment, on a plane, at least some of the plurality of first dummy pads may have a substantially same length as the signal pads disposed adjacent to the some of the plurality of first dummy pads in the first direction in a plan view, and have a substantially same length as the signal pads disposed adjacent to the some of the plurality of first dummy pads in the second direction in a plan view.

In an embodiment, the display device may further include a second dummy pad having a stacked structure different from that of the first dummy pad, wherein the second dummy pad may not include the dummy pattern.

In an embodiment of the inventive concept, an electronic apparatus includes: a display panel including a display region and a non-display region adjacent to the display region; and an electronic component which is disposed in the non-display region, is electrically connected to the display panel, and includes a signal bump and a dummy bump, wherein the display panel includes a base layer, insulating layers disposed on the base layer, a pixel disposed in the display region, a signal pad disposed in the non-display region and corresponding to the signal bump, and a dummy pad disposed in the non-display region and corresponding to the dummy bump, the signal pad includes a first conductive pattern, an insulating pattern disposed on the first conductive pattern, and a second conductive pattern disposed on the insulating pattern, the dummy pad includes the first conductive pattern and a dummy pattern disposed on the first conductive pattern, and a hardness of the dummy pattern is higher than a hardness of the insulating pattern.

In an embodiment, the dummy pattern and the second conductive pattern may include a same material.

In an embodiment, the dummy pattern may include metal.

In an embodiment, a lower surface of the dummy pattern may be convex in a direction toward the base layer.

In an embodiment, a lower surface of the base layer corresponding to the dummy pad may protrude than a lower surface of the base layer corresponding to the signal pad.

In an embodiment, the dummy pad may be electrically isolated.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a combined perspective view of an electronic apparatus according to an embodiment of the inventive concept;

FIG. 2 is an exploded perspective view of an electronic apparatus according to an embodiment of the inventive concept;

FIG. 3 is a cross-sectional view of a display device according to an embodiment of the inventive concept;

FIG. 4 is a plan view of a display panel according to an embodiment of the inventive concept;

FIG. 5 is a cross-sectional view of a display panel according to an embodiment of the inventive concept;

FIG. 6A is a cross-sectional view of an input sensor according to an embodiment of the inventive concept;

FIG. 6B is a plan view of an input sensor according to an embodiment of the inventive concept;

FIG. 6C is a cross-sectional view taken along line X-X′ of FIG. 6B;

FIG. 7 is an enlarged exploded perspective view of a pad region of a display device according to an embodiment of the inventive concept;

FIG. 8 is a plan view illustrating a pad region of a display panel according to an embodiment of the inventive concept;

FIG. 9A is an enlarged plan view of a signal pad according to an embodiment of the inventive concept, and FIGS. 9B and 9C are respectively cross-sectional views of the signal pad;

FIG. 10A is an enlarged plan view of a dummy pad according to an embodiment of the inventive concept, and FIG. 10B is a cross-sectional view of the dummy pad;

FIG. 11 is a cross-sectional view of a portion of a display panel according to an embodiment of the inventive concept;

FIG. 12 is a cross-sectional view of a portion of a display device to which a driver chip according to an embodiment of the inventive concept is connected; and FIGS. 13 and 14 are respectively enlarged plan views of a dummy pad according to other embodiments of the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc., may be used herein to describe various elements, the elements are not to be limited by these terms. These terms are only used to distinguish one element from another element. For instance, a first element could be termed a second element without departing from the scope of the inventive concept. Similarly, a second element could be termed a first element. In this specification, the singular expressions “a”, “an” and “the” are intended to include the plural forms as well, unless the context clearly indicates otherwise.

In addition, the terms “below”, “on the lower side”, “above”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

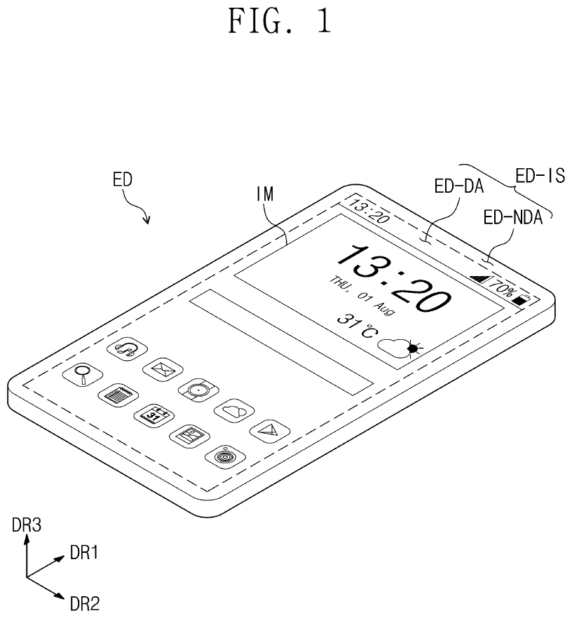

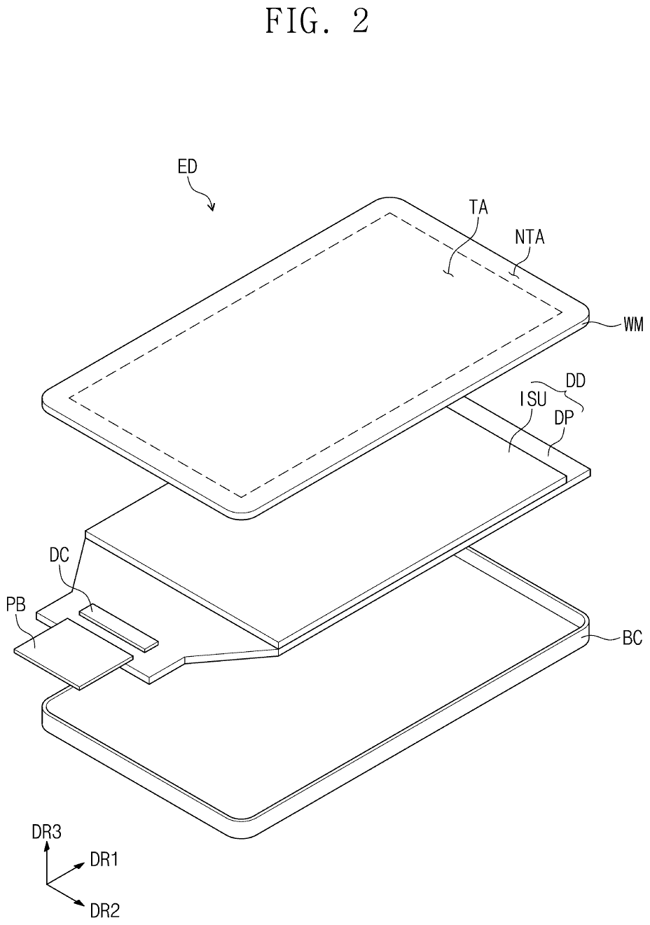

FIG. 1 is a perspective view of an electronic apparatus ED according to an embodiment of the inventive concept. FIG. 2 is an exploded perspective view of an electronic apparatus ED according to an embodiment of the inventive concept.

In FIGS. 1 and 2, a mobile phone terminal is exemplarily illustrated as the electronic apparatus ED. The electronic apparatus ED according to the inventive concept may be large-sized electronic apparatuses such as a television and a monitor, as well as, to small-and medium-sized apparatuses such as a tablet, a car navigation system, a game console, and a smart watch.

Referring to FIG. 1, the electronic apparatus ED may display an image IM through a display surface ED-IS. Icon images are exemplarily illustrated as the image IM. The display surface ED-IS is parallel to a plane defined by a first direction DR1 and a second direction DR2. A normal direction of the display surface ED-IS, that is, a thickness direction of the electronic apparatus ED is indicated as a third direction DR3. In this specification, the wording “when viewed on a plane” or “in a plan view” may mean a case when viewed in the third direction DR3. A front surface (or an upper surface) and a rear surface (or a lower surface) of each layer or unit to be described below are defined on the basis of the third direction DR3.

Also, the display surface ED-IS may include a display region ED-DA in which the image IM is displayed and a non-display region ED-NDA disposed adjacent to the display region ED-DA. The non-display region ED-NDA is a region in which an image is not displayed. However, an embodiment of the inventive concept is not limited thereto and the non-display region ED-NDA may be disposed adjacent to any one side of the display region ED-DA or may be omitted.

Referring to FIG. 2, the electronic apparatus ED may include a window WM, a display device DD, and a housing BC. The housing BC may accommodate the display device DD and be coupled to the window WM. Although not illustrated, the electronic apparatus ED may further include other electronic modules which are electrically connected to a display panel DP and are accommodated in the housing BC. For example, the electronic apparatus ED may further include a main board, a circuit module mounted on the main board, a camera module, a power module, etc.

The window WM may be disposed on an upper part of the display device DD, and transmit an image provided from the display device DD to the outside. The window WM may include a transmission region TA and a non-transmission region NTA. The transmission region TA may overlap the display region ED-DA of FIG. 1 and have a shape corresponding to that of the display region ED-DA.

The non-transmission region NTA may overlap the non-display region ED-NDA (see FIG. 1) and have a shape corresponding to that of the non-display region ED-NDA (see FIG. 1). The non-transmission region NTA may be a region having a relatively lower light transmittance than the transmission region TA.

The display device DD may generate an image and detect an external input. The display device DD may include the display panel DP and an input sensor ISU. Although not illustrated, the display device DD may further include an anti-reflection member disposed on the input sensor ISU. The anti-reflection member may include a polarizer and a retarder, or a color filter and a black matrix.

According to an embodiment of the inventive concept, the display panel DP may be a light-emitting display panel, but the type of the display panel DP is not particularly limited. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, a nano LED, etc. Hereinafter, the display panel DP is described as an organic light-emitting display panel.

The input sensor ISU may include any one among a capacitive sensor, an optical sensor, an ultrasonic sensor, or an electromagnetic induction sensor. The input sensor ISU may be formed on the display panel DP through a continuous process, or may be manufactured separately, and then attached to an upper side of the display panel DP via an adhesive layer.

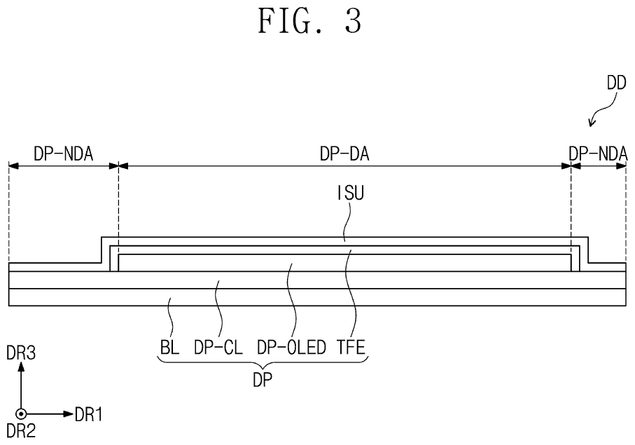

The display device DD according to an embodiment may further include a driver chip DC and a circuit board PB. FIG. 2 illustrates that the driver chip DC is mounted on the display panel DP, but an embodiment of the inventive concept is not limited thereto. The driver chip DC may generate a driving signal required for an operation of the display panel DP in response to a control signal transmitted from the circuit board PB. The circuit board PB connected to the display panel DP may be bent and disposed on a rear surface of the display panel DP. The circuit board PB may be disposed on one end of a base layer BL (see FIG. 3) and be electrically connected to a circuit element layer DP-CL (see FIG. 3).

In the display device DD according to an embodiment, a portion of the display panel DP may be bent such that the driver chip DC faces downward. A portion of the non-display region DP-NDA (see FIG. 3) of the display panel DP may also be bent. However, a bending portion is not limited thereto, and the circuit board PB may be bent.

The electronic apparatus ED described above is exemplarily illustrated as a mobile phone terminal, but in this specification, the electronic apparatus ED may be any apparatus including two or more connected electronic components. The display panel DP and the driver chip DC mounted on the display panel DP respectively correspond to different electronic components, and the electronic apparatus ED may include only these components. Only the display panel DP and the circuit board PB connected to the display panel DP may constitute the electronic apparatus ED, and only a main board and an electronic module mounted on the main board may constitute the electronic apparatus ED. Hereinafter, the description of the display device DD and the electronic apparatus ED according to the inventive concept will be mainly focused on a bonding structure of the display panel DP and the driver chip DC mounted on the display panel DP.

FIG. 3 is a cross-sectional view of a display device DD according to an embodiment of the inventive concept.

Referring to FIG. 3, a display panel DP may include a base layer BL, a circuit element layer DP-CL disposed on the base layer BL, a display element layer DP-OLED, and a thin-film encapsulation layer TFE. An input sensor ISU may be disposed on the thin-film encapsulation layer TFE.

The display panel DP may include a display region DP-DA and a non-display region DP-NDA. The display region DP-DA of the display panel DP corresponds to the display region ED-DA illustrated in FIG. 1 or the transmission region TA illustrated in FIG. 2, and the non-display region DP-NDA corresponds to the non-display region ED-NDA illustrated in FIG. 1 or the non-transmission region NTA illustrated in FIG. 2.

The base layer BL may include the display region DP-DA and the non-display region DP-NDA around the display region DP-DA. The base layer BL may include a synthetic resin film. The base layer BL may have a multi-layered structure. For example, the base layer BL may also have a three-layered structure of a synthetic resin layer, an inorganic layer, and a synthetic resin layer. In particular, the synthetic resin layer may be a polyimide-based resin layer and materials thereof are not particularly limited. The synthetic resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. Additionally, the base layer BL may include a glass substrate, a metal substrate, or an organic/inorganic composite material substrate, etc.

The circuit element layer DP-CL may include at least one insulating layer and a circuit element. The insulating layer may include at least one inorganic layer and at least one organic layer. The circuit element may include signal lines, a pixel driving circuit, etc. An insulating layer, a semiconductor layer, and a conductive layer are formed through a coating process, a deposition process, etc. Thereafter, the insulating layer, the semiconductor layer, and the conductive layer may be selectively patterned by performing a photolithography process and an etching process. In this process, a semiconductor pattern, a conductive pattern, a signal line, etc., are formed. Patterns disposed at the same layer are formed through the same process. Hereinafter, the wording, “patterns are formed through the same process” means that the patterns include the same material, have the same stacked structure and are formed at the same time.

The display element layer DP-OLED may include an organic light-emitting element. The display element layer DP-OLED may further include an organic layer such as a pixel-defining film.

The thin-film encapsulation layer TFE may be disposed on the circuit element layer DP-CL so as to cover the display element layer DP-OLED. The thin-film encapsulation layer TFE may protect pixels against moisture, oxygen, and external foreign substances. However, an embodiment of the inventive concept is not limited thereto, and the display panel DP may further include an additional insulating layer other than the thin-film encapsulation layer TFE. For example, an optical insulating layer for controlling a refractive index may be further included.

The input sensor ISU may be directly formed on the display panel DP. In this specification, the wording, “an A component being directly disposed or formed on a B component” means that an adhesive layer is not disposed between the A component and the B component. In this embodiment, the input sensor ISU may be directly formed on the display panel DP without an adhesive layer disposed between the display panel DP and the input sensor ISU through a continuous process. However, the idea of the inventive concept is not limited thereto, and the input sensor ISU may be provided as a separate panel and be coupled to the display panel DP via the adhesive layer. According to an embodiment, the input sensor ISU may also be omitted.

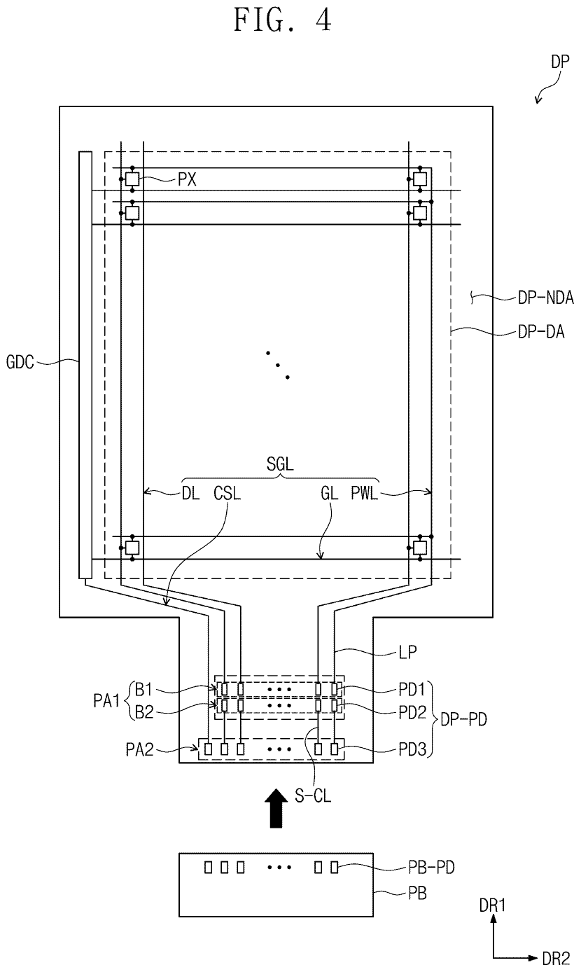

FIG. 4 is a plan view of a display panel DP according to an embodiment of the inventive concept. FIG. 4 illustrates a planar shape of the display panel DP illustrated in FIG. 3.

Referring to FIG. 4, the display panel DP may include a plurality of pixels PX, a gate driving circuit GDC, a plurality of signal lines SGL, and a plurality of pads DP-PD.

The pixels PX are disposed in a display region DP-DA. The pixels PX may each include a light-emitting element and a pixel driving circuit connected thereto. The gate driving circuit GDC sequentially outputs gate signals to a plurality of gate lines GL to be described later. A transistor of the gate driving circuit GDC may be formed through the same process as that for a transistor of the pixel PX, for example, a low temperature polycrystalline silicon (LTPS) process or a low temperature polycrystalline oxide (LTPO) process. The display panel DP may also further include another driving circuit which provides a light-emitting control signal to the pixels PX.

The signal lines SGL may include gate lines GL, data lines DL, a power supply line PWL, and a control signal line CSL. The gate lines GL are respectively connected to corresponding pixels PX among the pixels PX, and the data lines DL are respectively connected to corresponding pixels PX among the pixels PX. The power supply line PWL is connected to the pixels PX. The control signal line CSL may be connected to the gate driving circuit GDC and provide control signals to the gate driving circuit GDC.

The signal lines SGL may be disposed in the display region DP-DA and the non-display region DP-NDA. The signal lines SGL may each include a wire part LP. The wire part LP may be disposed in the display region DP-DA and the non-display region DP-NDA.

A plurality of pads DP-PD may include first pads PD1, second pads PD2, and third pads PD3. A region in which the first pads PD1 and the second pads PD2 are disposed may be defined as a first pad region PA1, and a region in which the third pads PD3 are disposed may be defined as a second pad region PA2.

The first pad region PA1 is a region to which the driver chip DC (see FIG. 2) is connected to the display panel DP, and the second pad region PA2 is a region to which the circuit board PB (see FIG. 2) is connected to the display panel DP. The first pad region PA1 may include a first region B1 in which the first pads PD1 are disposed and a second region B2 in which the second pads PD2 are disposed. The first pad region PA1 and the second pad region PA2 may be disposed within the non-display region DP-NDA. The first pad region PA1 and the second pad region PA2 may be spaced apart from each other in the first direction DR1. The first pad region PA1 may be disposed closer to the display region DP-DA than the second pad region PA2, and the second pad region PA2 may be spaced apart from the display region DP-DA with the first pad region PA1 disposed therebetween.

The first pads PD1 may be respectively connected to corresponding data lines DL among the data lines DL. Although not illustrated, the first pads PD1 and the second pads PD2 may be electrically connected to each other. The second pads PD2 may be connected to the third pads PD3 via connection signal lines S-CL.

The circuit board PB may include a plurality of circuit pads PB-PD. The circuit pads PB-PD may be arranged in the second direction DR2. The circuit pads PB-PD of the circuit board PB may be connected to the third pads PD3 in the second pad region PA2 to be in contact with the third pads PD3.

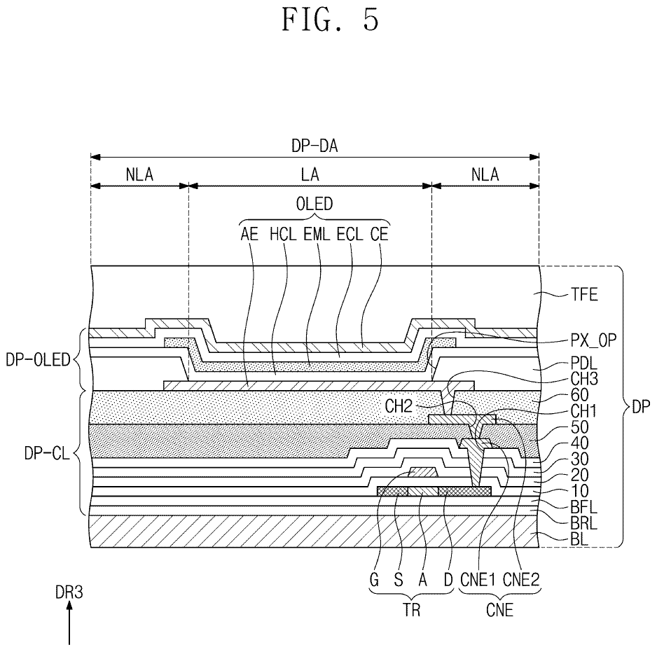

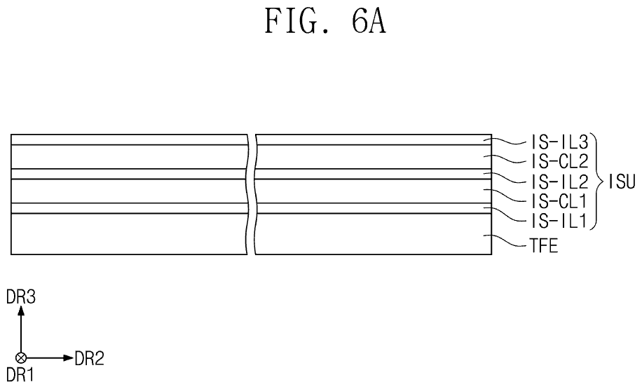

FIG. 5 is a cross-sectional view of a display panel DP according to an embodiment of the inventive concept.

Referring to FIG. 5, the display panel DP may include a base layer BL, a circuit element layer DP-CL disposed on the base layer BL, a display element layer DP-OLED, and a thin-film encapsulation layer TFE.

A plurality of insulating layers are disposed on an upper surface of the base layer BL. The plurality of insulating layers may include a barrier layer BRL and a buffer layer BFL. The plurality of insulating layers may further include a first insulating layer 10 to a sixth insulating layer 60. The barrier layer BRL prevents foreign substances from being introduced from the outside. The barrier layer BRL may include a silicon oxide layer and a silicon nitride layer. The silicon oxide layer and the silicon nitride layer may each be provided in plurality, and the silicon oxide layers and the silicon nitride layers may be alternately stacked.

The buffer layer BFL improves a bonding force between the base layer BL and a semiconductor pattern and/or a conductive pattern. The buffer layer BFL may include a silicon oxide layer and a silicon nitride layer. The silicon oxide layer and the silicon nitride layer may be alternately stacked.

The semiconductor pattern may be disposed on the buffer layer BFL. The semiconductor pattern may include polysilicon. The semiconductor pattern may include an amorphous or crystalline silicon semiconductor, or a metal oxide semiconductor. Meanwhile, FIG. 5 illustrates a part of a semiconductor pattern, and a semiconductor pattern may be further disposed in another region of the display panel DP in a plan view. The semiconductor pattern may be doped with an N-type dopant or a P-type dopant. The semiconductor pattern may include a highly-doped region and a lightly-doped region. The highly-doped region may have conductivity higher than that of the lightly-doped region, and substantially serve as a source S and a drain D of a transistor TR. The lightly-doped region may substantially correspond to an active A (or a channel) of the transistor TR.

A drain D, an active A, and a source S may be disposed on the buffer layer BFL in the semiconductor pattern. The drain D, the active A, and the source S may define the transistor TR together with a gate G to be described later. When the display panel DP includes another transistor other than the transistor TR, the other transistor may include a material different from that of the transistor TR and be disposed at a different layer from the transistor TR. The source S, the active A, and the drain D of the transistor TR may be portions of the semiconductor pattern.

The first insulating layer 10 may be disposed on the buffer layer BFL. The first insulating layer 10 may cover the semiconductor pattern. The gate G of the transistor TR may be disposed on the first insulating layer 10. The second insulating layer 20 may be disposed on the gate G. The gate G may be a part of a metal pattern. The gate G may overlap the active A. During the process of doping the semiconductor pattern, the gate G may function as a self-aligned mask.

The gate G may include at least one of titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), etc., but an embodiment of the inventive concept is not limited thereto.

The second insulating layer 20 covering the gate G may be disposed on the first insulating layer 10. The transistor TR according to an embodiment may further include an upper electrode which is disposed on the second insulating layer 20 and overlaps the gate G. The third insulating layer 30 may be disposed on the second insulating layer 20. The fourth insulating layer 40 may be disposed on the third insulating layer 30. The first to fourth insulating layers 10 to 40 may each be an inorganic layer and/or an organic layer, and have a single-or multi-layered structure.

A connection electrode CNE may include a first connection electrode CNE1 and a second connection electrode CNE2 for connecting the transistor TR and a light-emitting element OLED. The first connection electrode CNE1 may be disposed on the fourth insulating layer 40 and be connected to the drain D via a first contact hole CH1 defined in the first to fourth insulating layers 10 to 40.

The fifth insulating layer 50 may be disposed on the fourth insulating layer 40 on the first connection electrode CNE1. The fifth insulating layer 50 may be an organic layer. The second connection electrode CNE2 may be disposed on the fifth insulating layer 50. The second connection electrode CNE2 may be connected to the first connection electrode CNE1 via a second contact hole CH2 defined in the fifth insulating layer 50.

The sixth insulating layer 60 may be disposed on the second connection electrode CNE2. The layers ranging from the buffer layer BFL to the sixth insulating layer 60 may be defined as the circuit element layer DP-CL. The sixth insulating layer 60 may be an organic layer. A first electrode AE may be disposed on the sixth insulating layer 60. The first electrode AE may be connected to the second connection electrode CNE2 via a third contact hole CH3 defined in the sixth insulating layer 60. The first electrode AE may be connected to the transistor TR via the first and second connection electrodes CNE1 and CNE2. A pixel-defining film PDL, in which an opening PX_OP which is disposed in a partial area of the first electrode AE is defined, may be disposed on the first electrode AE and the sixth insulating layer 60.

A hole control layer HCL may be disposed on the first electrode AE and the pixel-defining film PDL. The hole control layer HCL may include a hole transport layer and a hole injection layer.

A light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light having one color of red, green, or blue.

An electron control layer ECL may be disposed on the light-emitting layer EML and the hole control layer HCL. The electron control layer ECL may include an electron transport layer and an electron injection layer. The hole control layer HCL and the electron control layer ECL may be disposed in a light-emitting region LA and a non-light-emitting region NLA in common.

A second electrode CE may be disposed on the electron control layer ECL. The second electrode CE may be disposed in the pixels PX (see FIG. 4) in common. The layers constituting the light-emitting element OLED may be defined as the display element layer DP-OLED.

The thin-film encapsulation layer TFE may be disposed on the second electrode CE to cover the pixel PX (see FIG. 4). Although not illustrated, the thin-film encapsulation layer TFE may include a plurality of layers. Some of the plurality of layers may include an inorganic layer which protects the pixel PX (see FIG. 4) against moisture or oxygen. The others of the plurality of layers may include an organic layer which protects the pixel PX (see FIG. 4) against foreign substances such as dust particles.

A first voltage may be applied to the first electrode AE through the transistor TR, and a second voltage having a lower level than the first voltage may be applied to the second electrode CE. Holes and electrons injected into the light-emitting layer EML are combined to form excitons, and the excitons transition to a ground state, so that the light-emitting element OLED may emit light.

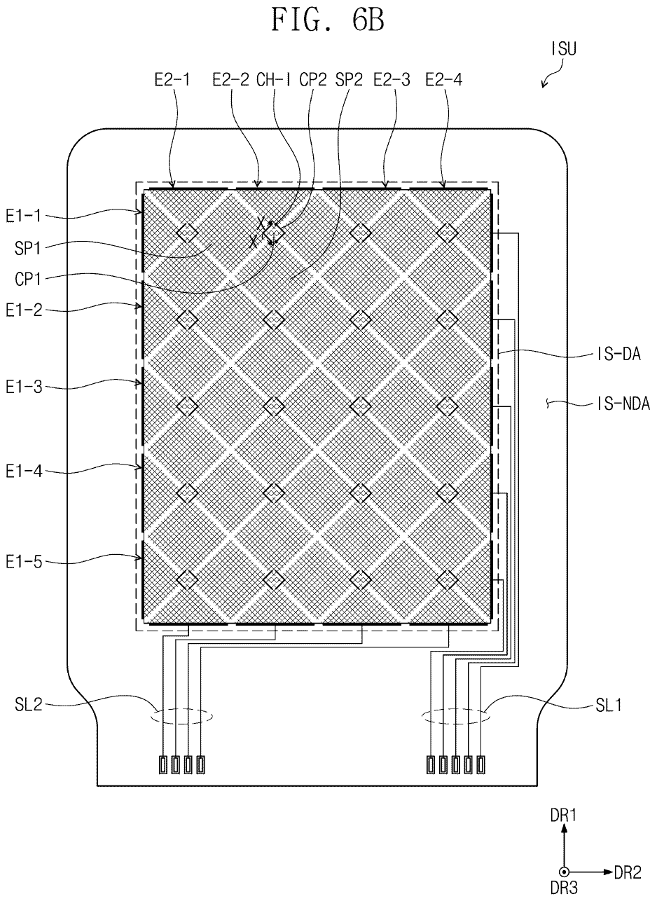

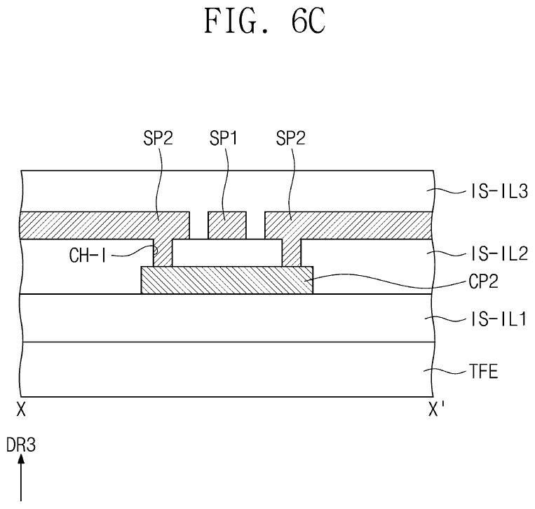

FIG. 6A is a cross-sectional view of an input sensor ISU according to an embodiment of the inventive concept. FIG. 6B is a plan view of the input sensor ISU according to an embodiment of the inventive concept. FIG. 6C is a cross-sectional view taken along line X-X′ of FIG. 6B.

The input sensor ISU may include a first insulating layer IS-IL1 (hereinafter, a first sensor insulating layer), a first conductive pattern layer IS-CL1, a second insulating layer IS-IL2 (hereinafter, a second sensor insulating layer), a second conductive pattern layer IS-CL2, and a third insulating layer IS-IL3 (hereinafter, a third sensor insulating layer). The first sensor insulating layer IS-IL1 may be directly formed on the thin-film encapsulation layer TFE.

According to an embodiment of the inventive concept, the first sensor insulating layer IS-IL1 and/or the third sensor insulating layer IS-IL3 may be omitted. When the first sensor insulating layer IS-IL1 is omitted, the first conductive pattern layer IS-CL1 may be directly formed on the uppermost insulating layer of the thin-film encapsulation layer TFE. The third sensor insulating layer IS-IL3 may also be replaced with an insulating layer of an anti-reflection member disposed on the adhesive layer or the input sensor ISU.

The first conductive pattern layer IS-CL1 and the second conductive pattern layer IS-CL2 may each have a single-layered structure or a multi-layered structure in which layers are stacked along the third direction DR3. Multi-layered conductive patterns may include at least two layers among transparent conductive layers and metal layers. The multi-layered conductive patterns may include metal layers including different metals. The transparent conductive layer may include indium tin oxide (ITO), indium zinc oxide (IZO), zinc oxide (ZnO), indium tin zinc oxide (ITZO), PEDOT, metal nanowires, or graphene. The metal layer may include molybdenum, silver, titanium, copper, aluminum, or an alloy thereof. A detailed description of a stacked structure of each of the first conductive pattern layer IS-CL1 and the second conductive pattern layer IS-CL2 will be described later.

In this embodiment, the first sensor insulating layer IS-IL1 to the third sensor insulating layer IS-IL3 may each include an inorganic layer or an organic layer. The above-described inorganic layers may include silicon oxide, silicon nitride, or silicon oxynitride. According to an embodiment of the inventive concept, at least one among the first sensor insulating layer IS-IL1 to the third sensor insulating layer IS-IL3 may include an organic layer. For example, the third sensor insulating layer IS-IL3 may include an organic layer. The organic layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

Referring to FIG. 6B, the input sensor ISU may include a sensing region IS-DA and a non-sensing region IS-NDA adjacent to the sensing region IS-DA. The sensing region IS-DA and the non-sensing region IS-NDA may respectively correspond to the display region DP-DA and the non-display region DP-NDA which are illustrated in FIG. 4.

The input sensor ISU may include a plurality of sensing electrodes disposed in the sensing region IS-DA. The sensing electrodes may include first sensing electrodes E1-1 to E1-5 (hereinafter, first electrodes) and second sensing electrodes E2-1 to E2-4 (hereinafter, second electrodes), which are mutually insulated and cross each other. The input sensor ISU may include first signal lines SL1 electrically connected to the first electrodes E1-1 to E1-5, and second signal lines SL2 electrically connected to the second electrodes E2-1 to E2-4, and the first signal lines SL1 and the second signal lines SL2 are disposed in the non-sensing region IS-NDA. The first electrodes E1-1 to E1-5, the second electrodes E2-1 to E2-4, the first signal lines SL1, and the second signal lines SL2 may be formed using the first conductive pattern layer IS-CL1 and the second conductive pattern layer IS-CL2 described with reference to FIG. 6A.

The first electrodes E1-1 to E1-5 and the second electrodes E2-1 to E2-4 may each include a plurality of conductive lines which cross each other. A plurality of conductive lines may define a plurality of openings, and the first electrodes E1-1 to E1-5, and the second electrodes E2-1 to E2-4 may form a mesh shape. The plurality of openings may each be defined to correspond to the opening PX_OP of the pixel-defining film PDL illustrated in FIG. 5.

One of the first electrodes E1-1 to E1-5 or the second electrodes E2-1 to E2-4 may have an integrated shape. In this embodiment, the first electrodes E1-1 to E1-5 having an integrated shape are exemplarily illustrated. The first electrodes E1-1 to E1-5 may include sensing portions SP1 and middle portions CP1. A portion of conductive patterns of the second conductive pattern layer IS-CL2 described above may correspond to the first electrodes E1-1 to E1-5.

The second electrodes E2-1 to E2-4 may respectively include sensing patterns SP2 and bridge patterns CP2 (or connection patterns). As illustrated in FIGS. 6B and 6C, two adjacent sensing patterns SP2 may be connected to two bridge patterns CP2 via a contact hole CH-I passing through the second sensor insulating layer IS-IL2, but the number of the bridge patterns CP2 is not limited. A portion of conductive patterns of the second conductive pattern layer IS-CL2 described above may correspond to the sensing patterns SP2. A portion of conductive patterns of the first conductive pattern layer IS-CL1 described above may correspond to the bridge patterns CP2.

One of the first signal lines SL1 or the second signal lines SL2 transmits a transmission signal for detecting an external input from an external circuit to a corresponding electrode among the first electrodes E1-1 to E1-5 and the second electrodes E2-1 to E2-4, and the other thereof transmits capacitance change between the first electrodes E1-1 to E1-5 and the second electrodes E2-1 to E2-4 to an external circuit as a reception signal.

A portion of conductive patterns of the second conductive pattern layer IS-CL2 described above may correspond to the first signal lines SL1 and the second signal lines SL2. The first signal lines SL1 and the second signal lines SL2 may have a structure of a plurality of layers or include a first layer line, formed from the above-described first conductive pattern layer IS-CL1, and a second layer line formed from the above-described second conductive pattern layer IS-CL2. The first layer line and the second layer line may be connected via a contact hole passing through the second sensor insulating layer IS-IL2 (see FIG. 6A).

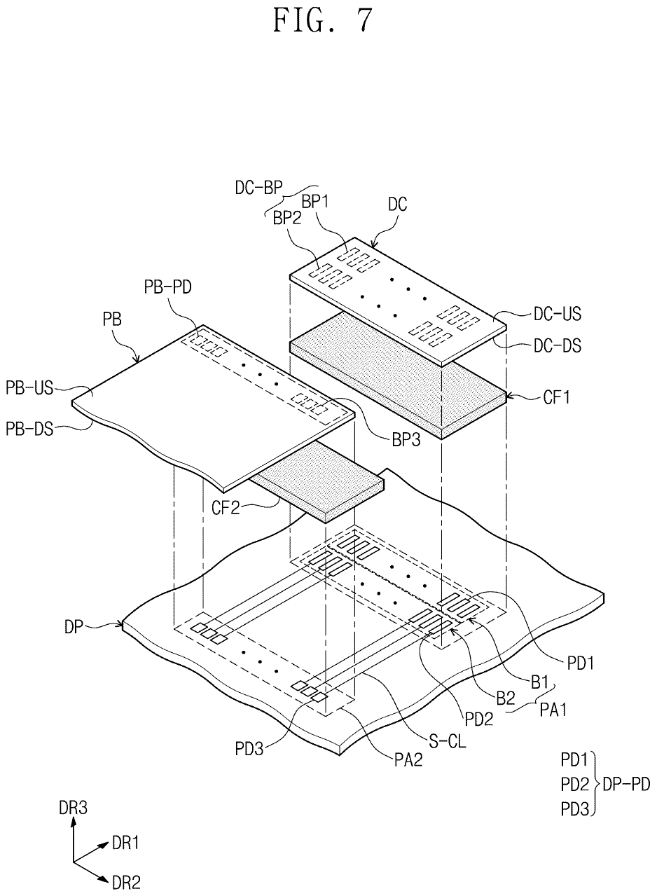

FIG. 7 is an enlarged exploded perspective view of pad regions PA1 and PA2 of a display device DD according to an embodiment of the inventive concept. For example, FIG. 7 illustrates that a driver chip DC and a circuit board PB are exploded from a display panel DP. First pads PD1, second pads PD2, connection signal lines S-CL, and third pads PD3 which are illustrated in FIG. 7 are identical or similar to those of FIG. 4, and thus the detailed description thereof may be omitted.

The driver chip DC may be connected to a first pad region PA1 via a first adhesive layer CF1, and the circuit board PB may be connected to a second pad region PA2 via a second adhesive layer CF2.

According to an embodiment of the inventive concept, the first adhesive layer CF1 and the second adhesive layer CF2 may be non-conductive films. That is, the first adhesive layer CF1 and the second adhesive layer CF2 may not include conductive balls and include a synthetic resin with adhesiveness. The synthetic resin is not required to maintain an arrangement of conductive balls and thus may have a relatively low viscosity.

When the first adhesive layer CF1 is cured, the first pads PD1 and first bumps BP1 on the driver chip DC may be fixed while being in contact with each other, and the second pads PD2 and second bumps BP2 on the driver chip DC may be fixed while being in contact with each other. When the second adhesive layer CF2 is cured, the third pads PD3 and third bumps BP3 connected to circuit pads may PB-PD be also fixed while being in contact with each other.

The driver chip DC may include a driving integrated circuit and driving bumps DC-BP mounted on the driver chip DC. The driver chip DC may include an upper surface DC-US and a lower surface DC-DS, and the lower surface DC-DS may be a surface facing the first pad PD1 and the second pad PD2. The driving bumps DC-BP may be disposed on the lower surface DC-DS of the driver chip DC.

The driving bumps DC-BP may include the first bumps BP1 electrically connected to the respective first pads PD1 and the second bumps BP2 electrically connected to the respective second pads PD2. The first bumps BP1 may be arranged along the second direction DR2, and the second bumps BP2 may be spaced apart from the first bumps BP1 in the first direction DR1 and be arranged along the second direction DR2.

The driver chip DC may receive first signals from the outside via the second pads PD2 and the second bumps BP2. The driver chip DC may provide second signals generated on the basis of the first signals to the first pads PD1 via the first bumps BP1. For example, the driver chip DC may include a data driving circuit. The first signal may be an image signal which is a digital signal applied from the outside, and the second signal may be a data signal which is an analog signal. The driver chip DC may generate an analog voltage corresponding to a grayscale value of an image signal. The data signal may be provided to the pixel PX via the data line DL illustrated in FIG. 4.

For convenience of description, FIG. 7 illustrates planar shapes of the driving bumps DC-BP as a dotted line, but the first bumps BP1 and the second bumps BP2 may each have a shape protruding from the lower surface DC-DS of the driver chip DC and exposed to the outside.

The circuit board PB may be disposed on the display panel DP. The circuit board PB may be disposed on the third pads PD3. The circuit board PB may include an upper surface PB-US and a lower surface PB-DS, and the lower surface PB-DS may be a surface facing the third pads PD3. The circuit board PB may include a plurality of circuit pads PB-PD electrically connected to the third pads PD3. The circuit pads PB-PD may be disposed on the lower surface PB-DS of the circuit board PB. The circuit pads PB-PD may be arranged in the second direction DR2. The circuit board PB may provide an image signal, a driving voltage, and other control signals to the driver chip DC.

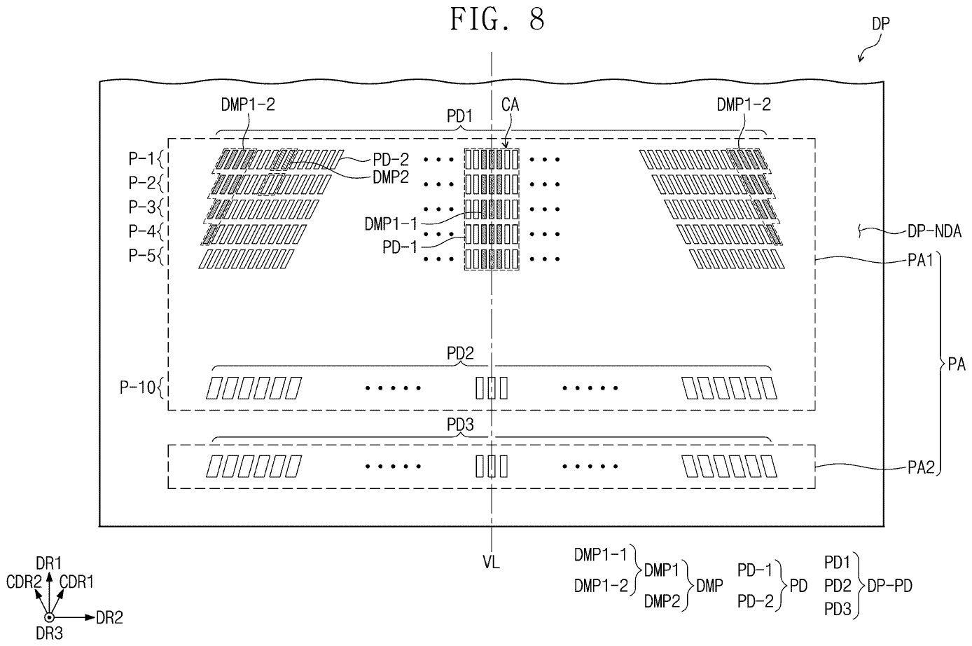

FIG. 8 is a plan view illustrating a pad region PA of a display panel DP according to an embodiment of the inventive concept. The pad region PA may include a first pad region PA1 and a second pad region PA2. FIG. 8 is an enlarged view illustrating the first pad region PA1 and the second pad region PA2. The first pad region PA1 and the second pad region PA2 are disposed in a non-display region DP-NDA of the display panel DP. The driver chip DC (see FIG. 7) is connected to the first pad region PA1 and the circuit board PB (see FIG. 7) is connected to the second pad region PA2.

The description of the first pad region PA1 may also be similarly applied to the second pad region PA2, and the description of first pads PD1 and second pads PD2 may be similarly applied to third pads PD3 as well. Additionally, in this specification, the first direction DR1 may be referred to as a column direction, and the second direction DR2 may also be referred to as a row direction.

The first pads PD1 may include a signal pad PD and a dummy pad DMP arranged side by side with the signal pad PD. The signal pad PD may be referred to as pads each of which is electrically connected to a data line DL (see FIG. 4) and the dummy pad DMP may be referred to as pads each of which is electrically isolated. The dummy pad DMP may be located to be spaced apart from the signal pad PD. The first pads PD1 may include a plurality of input rows P-1, P-2, P-3, P-4, and P-5 extending in the second direction DR2. The second pads PD2 may include an output row P-10 extending in the second direction DR2. Intervals between the first pads PD1 disposed at the same input row may be equal to each other. The description of one row among a plurality of rows may be similarly applied to the other rows as well.

Hereinafter, FIG. 8 will be described on the basis of one row. A first center pad of the first pads PD1 which is disposed at the center in the second direction DR2 may be disposed on a reference line VL. A central region CA of the first pads PD1 may be defined as a region adjacent to the reference line VL. That is, the central region CA may be a region adjacent to the center of the first pads PD1 in the second direction DR2.

The signal pad PD disposed in the central region CA may be provided in plurality and the plurality of signal pads PD in the central region CA may each be a first signal pad PD-1. The plurality of first signal pads PD-1 may each extend in the first direction DR1. The dummy pad DMP disposed in the central region CA may be provided in plurality, and the plurality of dummy pads may each be a (1-1)-th dummy pad DMP1-1. The (1-1)-th dummy pads DMP1-1 may extend in the first direction DR1.

Among the first pads PD1, the first pads PD1 disposed on the left side of the central region CA may be disposed to have a preset inclination with respect to the reference line VL. The first pads PD1 disposed on the left side may extend in a first oblique direction CDR1 crossing the first direction DR1 and the second direction DR2. Among the first pads PD1, the first pads PD1 disposed on the right side of the reference line VL may extend in a second oblique direction CDR2 which is symmetrical to the first oblique direction CDR1 with respect to the first direction DR1. The first pads PD1 disposed on the left side may be disposed to form an acute angle in a clockwise direction with respect to the reference line VL. The first pads PD1 disposed on the right side may be disposed to form an acute angle in a counterclockwise direction with respect to the reference line VL.

Second signal pads PD-2 may be referred to as pads spaced apart from the first signal pads PD-1 in the second direction DR2. The second signal pads PD-2 may be disposed in an outer region of the central region CA of the first pads PD1. The second signal pads PD-2 may be disposed on the left side and the right side of the central region CA.

The signal pads PD may include the first signal pads PD-1 and the second signal pads PD-2, and first dummy pads DMP1 may include the (1-1)-th dummy pads DMP1-1 and the (1-2)-th dummy pads DMP1-2. At least some of the first dummy pads DMP1 may have the substantially same length as the signal pads PD in the first direction DR1, and may have the substantially same length as the signal pads PD in the second direction DR2.

(1-2)-th dummy pads DMP1-2 may be referred to as dummy pads spaced apart from the second signal pads PD-2 in the second direction DR2. The (1-2)-th dummy pads DMP1-2 may be disposed between the second signal pads PD-2 as well as on the outermost region of the first pads PD1 in the second direction DR2. That is, the (1-2)-th dummy pads DMP1-2 may be disposed in the outer region of the central region CA of the first pads PD1 and on the left side and the right side of the central region CA.

Meanwhile, in this specification, the wording, “the substantially same” includes a case where components have the completely same value of each of a length, a width, etc., as well as a case where in spite of being identically designed, components have the same value within a range of differences that may occur due to a process tolerance.

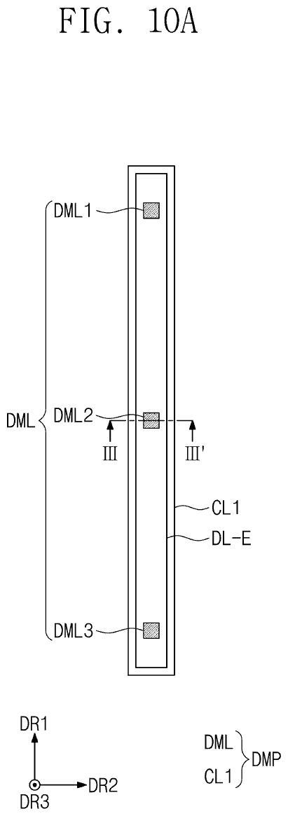

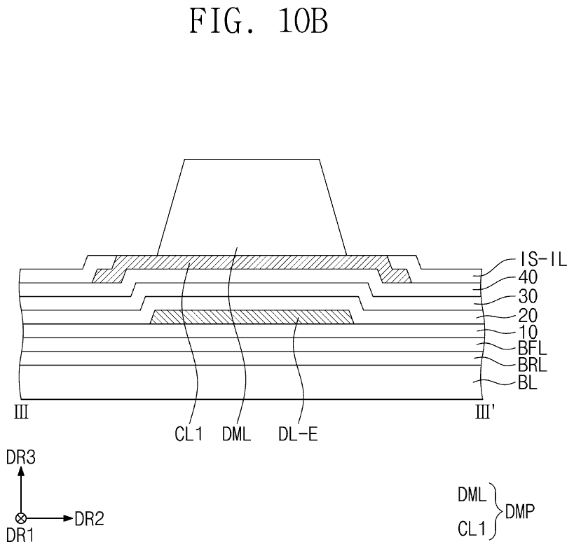

Second dummy pads DMP2 may be dummy pads having a stacked structure different from that of the first dummy pads DMP1. The second dummy pads DMP2 may be dummy pads which do not include a dummy pattern DML (see FIG. 10A) to be described later. The second dummy pads DMP2 are not necessarily included in the first pads PD1. The second dummy pads DMP2 may also be disposed between the signal pads PD, be disposed in the central region CA in which the (1-1)-th dummy pads DMP1-1 are disposed, and be disposed in the outermost region of the first pads PD1 in which the (1-2)-th dummy pads DMP1-2 are disposed. Additionally, the second dummy pads DMP2 may have the substantially same length as the first dummy pads DMP1 in the first direction DR1 and may have the substantially same length as the first dummy pads DMP1 in the second direction DR2.

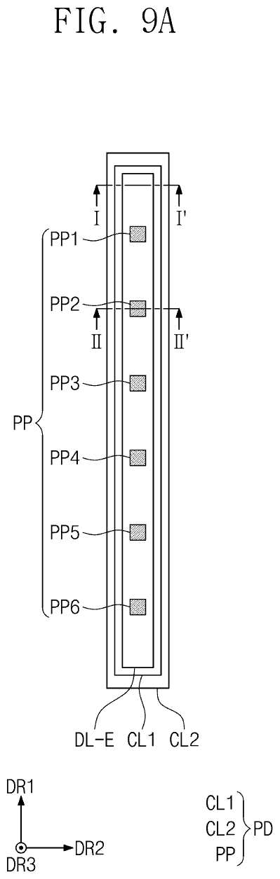

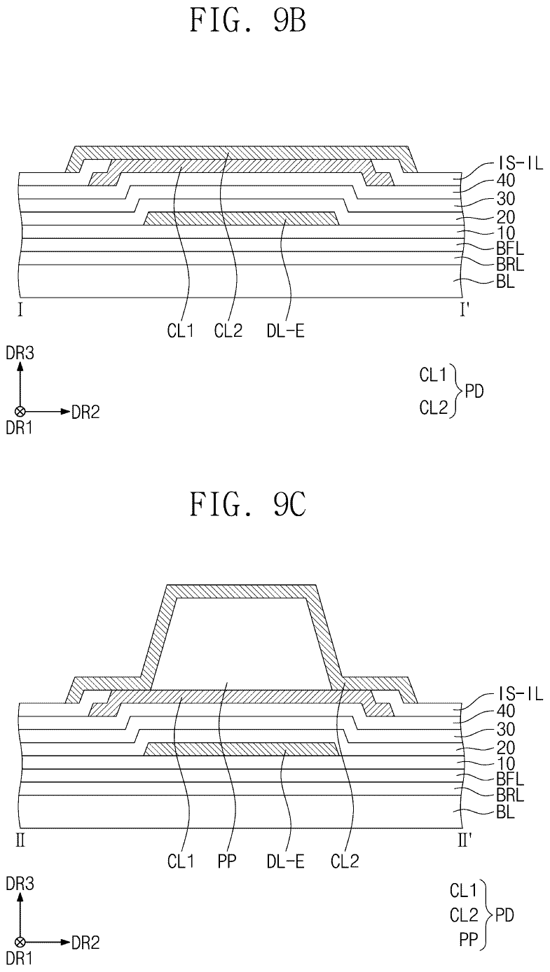

FIG. 9A is an enlarged plan view of a signal pad PD according to an embodiment of the inventive concept, and FIGS. 9B and 9C are cross-sectional views of the signal pad PD.

The signal pad PD may include a first conductive pattern CL1 and a second conductive pattern CL2, and an insulating pattern PP. FIG. 9A illustrates the data line DL (see FIG. 4) including an end DL-E as an example of the signal lines SGL (see FIG. 4), but other signal lines SGL illustrated in FIG. 4 may have the same configuration as disclosed in FIG. 9A. For convenience of description, only the end DL-E of the data line DL (see FIG. 4) is illustrated.

Although not illustrated in a plan view, the first conductive pattern CL1 may be connected to the end DL-E of the data line DL (see FIG. 4) via at least one contact hole. In a plan view, the end DL-E may have a shape extending in the first direction DR1. That is, the length or the width of the end DL-E in the first direction DR1 may be greater than the length or the width of the end DL-E in the second direction DR2.

FIG. 9A illustrates that one signal pad PD includes six insulating patterns PP1 to PP6, but the number of insulating patterns PP is not limited thereto. In a plan view, the insulating patterns PP may overlap a first conductive pattern CL1 and a second conductive pattern CL2. In a plan view, the insulating patterns PP may be arranged along the first direction DR1. The insulating patterns PP may be located to be spaced apart from each other in the first direction DR1.

The insulating patterns PP may include polymers. The insulating patterns PP may include thermosetting polymers. However, an embodiment of the inventive concept is not limited thereto and the insulating patterns PP may include thermoplastic polymers.

In a plan view, the insulating patterns PP are illustrated to have a square shape, but shapes of the insulating patterns PP are not limited thereto. For example, planar shapes of the insulating patterns PP may have a polygon, a circle, an oval, etc., other than a quadrilateral and a rectangle. Additionally, shapes of the insulating patterns PP are not limited to having the same shape.

In a plan view, the second conductive pattern CL2 may have an area greater than that of the first conductive pattern CL1, and the first conductive pattern CL1 may be disposed inside the second conductive pattern CL2. An additional conductive pattern may be further included other than the first conductive pattern CL1 and the second conductive pattern CL2, and an embodiment of the inventive concept is not limited thereto.

FIG. 9B illustrates a cross-section taken along line I-I′ of FIG. 9A, and FIG. 9C illustrates a cross-section taken along line II-II′ of FIG. 9A. In FIGS. 9B and 9C, the above-described components with reference to FIGS. 5 and 9A may be omitted.

Referring to FIGS. 9B and 9C, an end DL-E may be disposed on the first insulating layer 10. The end DL-E and the gate G (see FIG. 5) may be disposed at the same layer. The end DL-E and the gate G (see FIG. 5) may be formed through the same process and may include the same material. However, a position of the end DL-E is not limited thereto. Some of the plurality of signal lines and the gate G (see FIG. 5) may be disposed at the same layer, and other signal lines may also be disposed on the second insulating layer 20.

The first conductive pattern CL1 may be disposed on the fourth insulating layer 40. The first conductive pattern CL1 may be connected to the end DL-E via the contact hole passing through the second to fourth insulating layers 20, 30, and 40. That is, the first conductive pattern CL1 may be in contact with the end DL-E via the contact hole. The first conductive pattern CL1 and the end DL-E may be insulated by the second to fourth insulating layers 20, 30, and 40 which are disposed therebetween.

Referring to FIGS. 9B and 9C, the second conductive pattern CL2 may be disposed on the first conductive pattern CL1. A region of the second conductive pattern CL2 which does not overlap the insulating pattern PP may be in direct contact with the first conductive pattern CL1. A region of the second conductive pattern CL2 which overlaps the insulating pattern PP may be in contact with the insulating pattern PP.

Meanwhile, the first conductive pattern CL1 and the second conductive pattern CL2 may each include the same material as some components included in the above-described circuit element layer DP-CL (see FIG. 5). The first conductive pattern CL1 and the second conductive pattern CL2 may each include the same material as at least some of the conductive layers such as the connection electrode CNE (see FIG. 5).

In an embodiment, the first conductive pattern CL1 may be formed through the same process as that for the first connection electrode CNE1 (see FIG. 5), and the second conductive pattern CL2 may be formed through the same process as that for the second connection electrode CNE2 (see FIG. 5). The first conductive pattern CL1 and the first connection electrode CNE1 (see FIG. 5) may include the same material, and the second conductive pattern CL2 and the second connection electrode CNE2 (see FIG. 5) may include the same material.

In an embodiment, the second conductive pattern CL2 may be disposed on a sensor insulating layer IS-IL of the input sensor ISU (see FIG. 6A). The sensor insulating layer IS-IL may include at least one of a first sensor insulating layer IS-IL1 or a second sensor insulating layer IS-IL2 illustrated in FIG. 6A. The second conductive pattern CL2 may include at least one of the first conductive pattern layer IS-CL1 or the second conductive pattern layer IS-CL2 illustrated in FIG. 6A.

FIGS. 9B and 9C exemplarily illustrate an embodiment of the first conductive pattern CL1 disposed on the fourth insulating layer 40, but according to an embodiment, the first conductive pattern CL1 may also be disposed on the third insulating layer 30, and the fourth insulating layer 40 may not be disposed. However, an embodiment of the inventive concept is not limited thereto, and the combination of the connection electrodes formed through the same processes as those for the first and second conductive patterns CL1 and CL2 may be variously selected according to a stacked structure of the circuit element layer DP-CL (see FIG. 5) as long as the first and second conductive patterns CL1 and CL2 which are disposed on different layers may be provided.

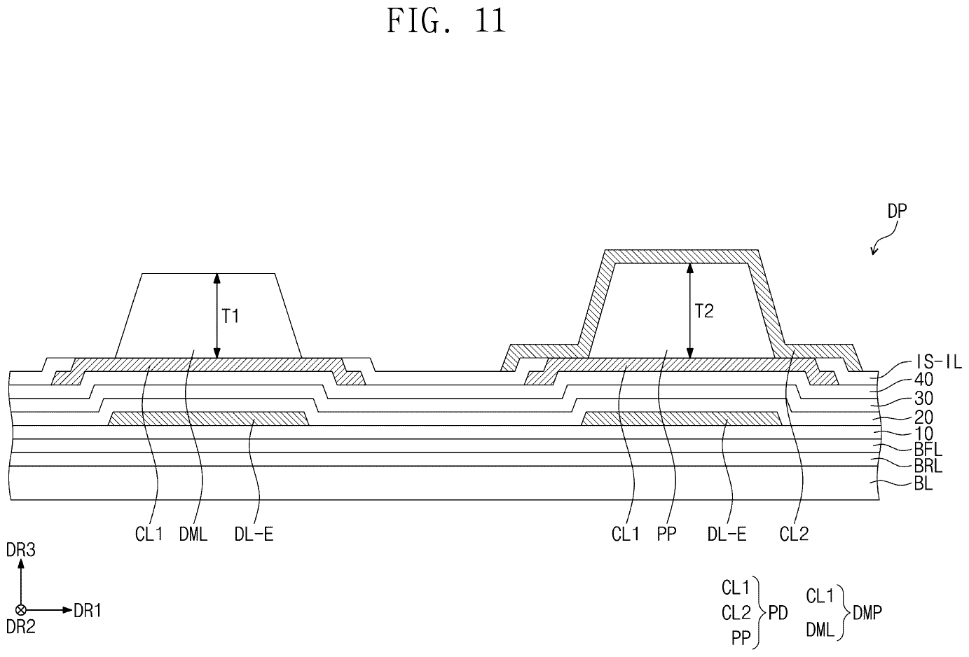

FIG. 10A is an enlarged plan view of a dummy pad DMP according to an embodiment of the inventive concept, and FIG. 10B is a cross-sectional view of the dummy pad DMP. FIG. 11 is a cross-sectional view of a portion of a display panel DP according to an embodiment of the inventive concept. FIG. 11 is a cross-sectional view of a portion of the pad region PA (see FIG. 8). In FIGS. 10A, 10B and 11, the description of the above-described components with reference to FIGS. 9A to 9C may be omitted.

The dummy pad DMP may be an electrically isolated conductive pattern. That is, the dummy pad DMP may be a floating pattern. The dummy pad DMP may be disposed between signal pads PD, and be disposed also in the outermost region of the signal pads PD. The dummy pad DMP may reduce electrical interference between adjacent signal pads PD, and fluctuation of potentials in the signal pads PD due to adjacent signal pads PD may also be reduced. Accordingly, noise between the signal pads PD is reduced, and thus electrical stability may be improved. Additionally, as the dummy pad DMP is disposed, a display panel DP and an electronic component may be prevented from being bent or cracked during the process of bonding the display panel DP and the electronic component.

As illustrated in FIG. 10A, in a plan view, the dummy pad DMP may include the first conductive pattern CL1 and a dummy pattern DML. In a plan view, the dummy pattern DML may be disposed inside the first conductive pattern CL1.

FIG. 10A illustrates that one dummy pad DMP includes three dummy patterns DML1 to DML3, but the number of the dummy patterns DML is not limited thereto. Additionally, in a plan view, the dummy patterns DML may overlap the first conductive pattern CL1. In a plan view, the dummy patterns DML may be arranged along the first direction DR1 and may be spaced apart from each other in the first direction DR1.

FIG. 10B illustrates a cross-section taken along line III-III′ of FIG. 10A. The dummy pattern DML may be disposed on the first conductive pattern CL1. Referring to FIGS. 10B and 11, even though the dummy pattern DML and the insulating pattern PP are disposed at the same layer, the dummy pattern DML and the insulating pattern PP may be formed through different processes. Additionally, the dummy pattern DML may include a material different from that of the insulating pattern PP.

The hardness of the dummy pattern DML according to an embodiment of the inventive concept is higher than the hardness of the insulating pattern PP. That is, the dummy pattern DML of the dummy pad DMP may have a physical pressure resistance greater than that of the insulating pattern PP of the signal pad, and thus it is difficult to be compressed or deformed due to physical pressure. Also, the dummy pattern DML may include metal. For example, the dummy pattern DML may include high-hardness metal such as titanium (Ti), aluminum (Al) or zirconium (Zr). Additionally, the dummy pattern DML may further include a high-hardness organic material such as polycarbonate, polyurethane, polyamide, or epoxy resin.

In an embodiment, the hardness of the dummy pattern DML may be higher than the hardness of the first conductive pattern CL1. That is, when a physical pressure is applied from an upper part to a lower part of the dummy pad DMP, the pressure applied to the dummy pattern DML may be transmitted to the first conductive pattern CL1, and thus the first conductive pattern CL1 may be compressed or deformed.

In an embodiment, the dummy pattern DML and the second conductive pattern CL2 may include a same material and may be formed through a same process. However, the dummy pattern DML may be formed through a separate process from the second conductive pattern CL2. For example, the second conductive pattern CL2 may be formed and then the dummy pattern DML having a different thickness may be formed through a separate process. However, the order of the above-described processes is not limited. The dummy pattern DML may be formed, and then the second conductive pattern CL2 may be formed as well.

As illustrated in FIG. 11, the thickness T1 of the dummy pattern DML before being connected to a driver chip DC (see FIG. 2) may be smaller than the thickness T2 of the insulating pattern PP before being connected to the driver chip DC (see FIG. 2). In an embodiment, the dummy pattern DML before being connected to the driver chip DC (see FIG. 2) may have the thickness T1 of about 1 μm to about 5 μm. Accordingly, during the bonding process with an electronic component, the signal pad PD may be connected to the driver chip DC (see FIG. 2) first to the electronic component before the dummy pad DMP is connected to the driver chip DC (see FIG. 2).

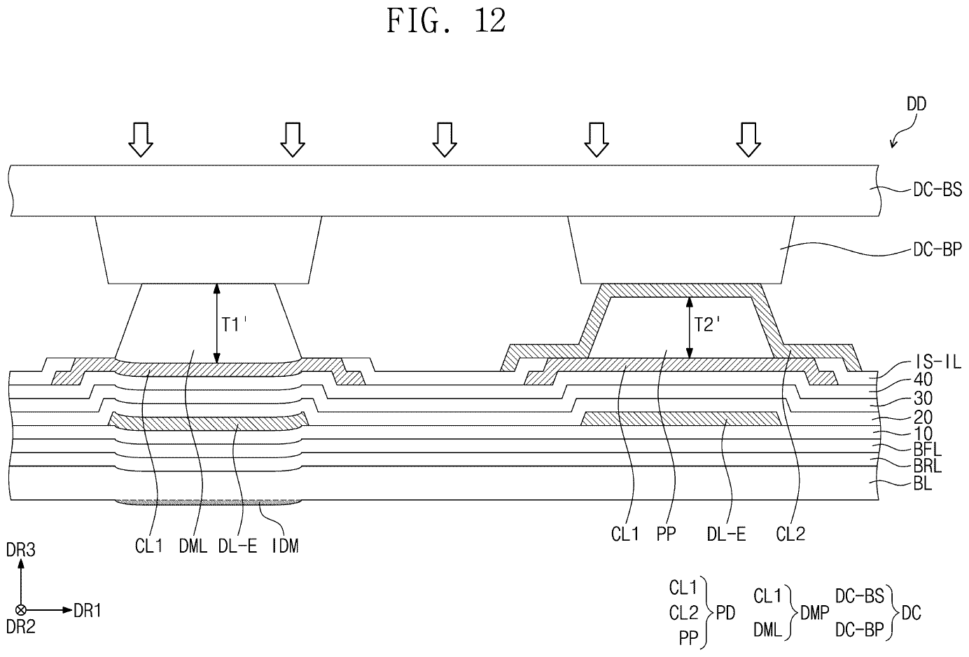

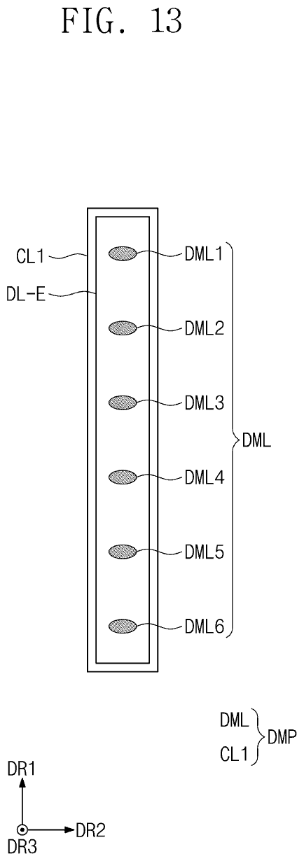

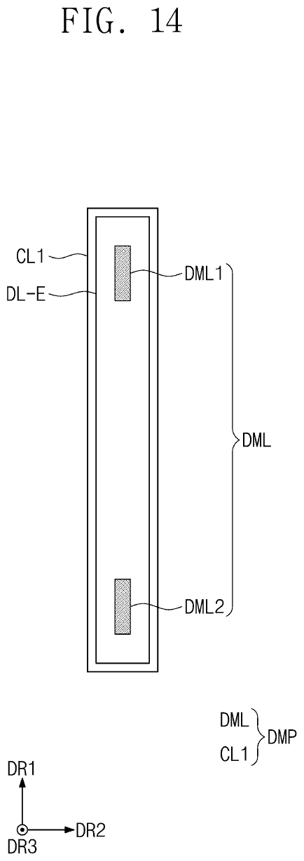

FIG. 12 is a cross-sectional view of a portion of a display device DD to which a driver chip DC according to an embodiment of the inventive concept is connected. FIG. 12 illustrates a state in which a signal pad PD and a dummy pad DMP are each in contact with the driver chip DC. Hereinafter, the description of the above-described components may be omitted.

The driver chip DC may include a driving integrated circuit DC-BS and a driving bump DC-BP disposed under the driving integrated circuit DC-BS. The driving bump DC-BP may include a signal bump and a dummy bump, and the signal bump and the dummy bump may respectively correspond to the signal pad PD and the dummy pad DMP.

The driving bump DC-BP of the driver chip DC may be in contact with the signal pad PD and the dummy pad DMP through a bonding process. The driving bump DC-BP may be in contact with the second conductive pattern CL2 of the signal pad PD and be in contact with the dummy pattern DML of the dummy pad DMP. Since the display device DD of the inventive concept does not include conductive particles such as conductive balls, even when the signal pads PD are densely disposed, short-circuit failure caused by conductive particles may be reduced. Additionally, conductive failure which occurs when conductive particles are not disposed between the signal pad PD and the driving bump DC-BP may be prevented, and thus electrical connection properties between the signal pads PD and the driving bumps DC-BP may be improved.

As illustrated in FIG. 12, the dummy pad DMP and the signal pad PD may have different stacked structures. During the process in which the dummy pad DMP and the signal pad PD each are connected to the driving bump DC-BP, pressures may be applied to insulating layers 10 to IS-IL and a base layer BL which are disposed below the dummy pad DMP and the signal pad PD. Pressures may be concentrated at portions of the dummy pad DMP and the signal pad PD which respectively overlap the driving bumps DC-BP.

As pressures are applied to the signal pad PD overlapping the signal bump, the insulating pattern PP may be compressed. As described above, since the hardness of the insulating pattern PP is lower than the hardness of the dummy pattern DML, when pressures are applied, the thickness T2 of the insulating pattern PP may be reduced. That is, the insulating pattern PP may serve as a buffer for absorbing a bonding pressure, and thus lower surfaces of the insulating layers 10 to IS-IL, a buffer layer BFL, a barrier layer BRL and the base layer BL which overlap the signal pad PD may not be deformed.

On the contrary, as pressures are applied to the dummy pattern DML overlapping the dummy bump, a lower surface of the dummy pattern DML may have a convex shape in a direction toward the base layer BL. Similarly, the lower surfaces of the insulating layers 10 to IS-IL, the buffer layer BFL, the barrier layer BRL and the base layer BL which overlap the dummy pattern DML may also have a convex shape in a direction toward the base layer BL.

In an embodiment of the inventive concept, the lower surface of the base layer BL corresponding to the dummy pad DMP may have a more protruded shape than the lower surface of the base layer BL corresponding to the signal pad PD. Accordingly, an indentation IDM, which is a dent mark caused by a bonding pressure, may be formed on the lower surface of the base layer BL corresponding to the dummy pattern DML. That is, the indentation IDM may be formed on a rear surface of a panel corresponding to the dummy pad DMP, and may not be formed on a rear surface of the panel corresponding to the signal pad PD. The indentation IDM may be used for checking flatness of an electronic component and a panel, and an unconnected region due to foreign substances. Accordingly, it is possible to easily detect an initial process failure. Additionally, since the indentation IDM is not formed on the signal pad PD, crack of the conductive pattern CL1 due to the bonding pressure may be reduced, and thus physical damage to the display panel may be reduced.

Referring to FIGS. 11 and 12, due to the bonding process, the thickness T1′ of the dummy pattern DML after being connected may be further reduced than or may be the same as the thickness T1 of the dummy pattern DML before being connected. Since the dummy pattern DML includes a high-hardness material, the dummy pattern DML does not absorb the bonding pressure, and thus pressures may be transmitted to the lower surface of the dummy pattern DML. On the contrary, the thickness T2′ of the insulating pattern PP after being connected may be further reduced than the thickness T2 of the insulating pattern PP before being connected. As described above, since the insulating pattern PP absorbs the bonding pressure, the thickness T2 of the insulating pattern PP may be reduced according to the bonding process. Therefore, the thickness variation of the dummy pattern DML according to the bonding process may be smaller than the thickness variation of the insulating pattern PP.

FIGS. 13 and 14 are respectively enlarged plan views of a dummy pad DMP according to other embodiments of the inventive concept. FIG. 13 illustrates that one dummy pad DMP includes six dummy patterns DML1 to DML6, and FIG. 14 illustrates that one dummy pad DMP includes two dummy patterns DML1 and DML2, but the number of the dummy patterns DML is not limited thereto.

Additionally, FIG. 13 illustrates that the dummy patterns DML have an oval shape, and FIG. 14 illustrates that the dummy patterns DML have a rectangular shape extended in the first direction DR1. However, planar shapes of the dummy patterns DML may also have a polygon, a circle, etc., other than a quadrilateral. Furthermore, shapes of the dummy patterns DML are not limited to having the same shape.

According to an embodiment of the inventive concept, a display panel may be connected to an electronic component without an anisotropic conductive film. A short-circuit failure caused by conductive particles may be reduced even when signal pads are densely disposed in a pad region.

An insulating pattern disposed on the signal pad of the display panel may allow a conductive pattern of the signal pad to protrude toward an electronic component. Accordingly, proximity between the signal pad of the display panel and a bump or a pad of the electronic component may be enhanced, and thus bonding properties may be improved.

Since a dummy pad disposed in the pad region of the display panel includes a dummy pattern having relatively higher hardness than an insulating pattern, an indentation may be formed on a rear surface of the display panel during a bonding process of the display panel and the electronic component. The indentation may be used for checking flatness of the electronic component and the display panel, and an unbonded region due to foreign substances, and thus it is possible to easily detect an initial process failure.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims. Therefore, the technical scope of the inventive concept is not to be limited to the contents stated in the detailed description of the specification, but should be determined by the claims.

What is claimed is:

1. A display device comprising:
a display panel including a display region and a non-display region adjacent to the display region;
a pixel disposed in the display region;
a signal line disposed in the display region and the non-display region, and electrically connected to the pixel;
a signal pad disposed in the non-display region and electrically connected to the signal line; and
a first dummy pad disposed in the non-display region and spaced apart from the signal pad,
wherein the signal pad includes a first conductive pattern electrically connected to an end of the signal line, an insulating pattern disposed on the first conductive pattern, and a second conductive pattern disposed on the insulating pattern,
wherein the first dummy pad includes the first conductive pattern, and a dummy pattern disposed on the first conductive pattern, and
wherein a hardness of the dummy pattern is higher than a hardness of the insulating pattern.

2. The display device of claim 1, wherein the dummy pattern and the second conductive pattern comprise a same material.

3. The display device of claim 1, wherein the dummy pattern comprises metal.

4. The display device of claim 1, wherein the hardness of the dummy pattern is higher than a hardness of the first conductive pattern.

5. The display device of claim 1, wherein the dummy pattern has a thickness of about 1 μm to about 5 μm.

6. The display device of claim 1, wherein the dummy pattern is disposed inside the first conductive pattern in a plan view.

7. The display device of claim 1, wherein the first dummy pad extends in one direction in a plan view,
wherein the dummy pattern is provided in plurality, and
wherein the plurality of dummy patterns are located to be spaced apart from each other in the one direction in a plan view.

8. The display device of claim 1, wherein the first dummy pad is electrically isolated.

9. The display device of claim 1, wherein the signal pad and the first dummy pad each are provided in plurality,
wherein the plurality of signal pads comprise first signal pads extending in a first direction in a plan view, and
wherein the plurality of first dummy pads comprise (1-1)-th dummy pads extending in the first direction in a plan view.

10. The display device of claim 9, wherein the plurality of signal pads further comprise second signal pads spaced apart from the first signal pads in a second direction crossing the first direction in a plan view,
wherein the second signal pads extend in an oblique direction crossing the first direction and the second direction,
wherein the plurality of first dummy pads further comprise (1-2)-th dummy pads spaced apart from the second signal pads in the second direction, and
wherein the (1-2)-th dummy pads extend in an oblique direction crossing the first direction and the second direction.

11. The display device of claim 10, wherein the first signal pads are disposed in a central region of the plurality of signal pads in the second direction in a plan view, and
wherein the (1-1)-th dummy pads are disposed in the central region in a plan view.

12. The display device of claim 10, wherein the (1-2)-th dummy pads are disposed in an outermost region of the plurality of signal pads within the second direction in a plan view.

13. The display device of claim 10, wherein at least some of the plurality of first dummy pads have a substantially same length as the signal pads disposed adjacent to the some of the plurality of first dummy pads in the first direction in a plan view and have a substantially same length as the signal pads disposed adjacent to the some of the plurality of first dummy pads in the second direction in a plan view.

14. The display device of claim 1, further comprising a second dummy pad having a stacked structure different from that of the first dummy pad,
wherein the second dummy pad does not include the dummy pattern.

15. An electronic apparatus comprising:
a display panel including a display region and a non-display region adjacent to the display region; and
an electronic component which is disposed in the non-display region, is electrically connected to the display panel, and includes a signal bump and a dummy bump,
wherein the display panel includes:
a base layer,
insulating layers disposed on the base layer,
a pixel disposed in the display region,
a signal pad disposed in the non-display region and corresponding to the signal bump; and
a dummy pad disposed in the non-display region and corresponding to the dummy bump,
wherein the signal pad includes a first conductive pattern, an insulating pattern disposed on the first conductive pattern, and a second conductive pattern disposed on the insulating pattern,
wherein the dummy pad includes the first conductive pattern and a dummy pattern disposed on the first conductive pattern, and
wherein a hardness of the dummy pattern is higher than a hardness of the insulating pattern.

16. The electronic apparatus of claim 15, wherein the dummy pattern and the second conductive pattern comprise a same material.

17. The electronic apparatus of claim 15, wherein the dummy pattern comprises metal.

18. The electronic apparatus of claim 15, wherein a lower surface of the dummy pattern is convex in a direction toward the base layer.

19. The electronic apparatus of claim 15, wherein a lower surface of the base layer corresponding to the dummy pad protrudes than a lower surface of the base layer corresponding to the signal pad.

20. The electronic apparatus of claim 15, wherein the dummy pad is electrically isolated.
